(19) United States
(12) Patent Application Publication
(10) Pub. No.: US 2026/0150222 A1
(43) Pub. Date: May 28, 2026

(54) CHASSIS AND ELECTRONIC DEVICE

(71) Applicant: Lenovo Global Technology (Taiwan) Limited., Taipei (TW)

(72) Inventors: Chih Kai CHANG, Taipei (TW); Chun Chi TSAI, Taipei (TW); Kuang Wei CHEN, Taipei (TW); Teh Cheng LIN, Taipei (TW); Han Chung CHANG, Taipei (TW)

(21) Appl. No.: 19/394,938

(22) Filed: Nov. 20, 2025

(30) Foreign Application Priority Data
Nov. 28, 2024 (CN) 202411723859.5

(51) Int. Cl. H05K 7/18

(52) U.S. Cl. CPC H05K 7/18

(57) ABSTRACT

Chassis includes case with first and second openings with axial directions thereof forming angle, lock member including press member located outside the case and limit member located inside the case along first direction of the first opening, and elastic member with first part fixed to outer contour of the case and second part configured to enter the case through the second opening to form locked state when the press member presses the elastic member or to exit the case through the second opening to form unlocked state when the press member is not pressing the elastic member. Insertion member of electronic component, when located in the first direction, drive the limit member to move so that the press member does not press the elastic member and the elastic member is in the unlocked state. When the elastic member is in the locked state, the electronic device abuts the second part.

### CROSS-REFERENCE TO RELATED APPLICATION

This application claims priority to Chinese Patent Application No. 202411723859.5, filed on Nov. 28, 2024, the entire content of which is incorporated herein by reference.

### TECHNICAL FIELD

The present disclosure generally relates to but is not limited to the electronic devices technology field and, more particularly, to a chassis and an electronic device.

### BACKGROUND

For an electronic device, electronic components need to be installed in a chassis. However, during the installation process, it is difficult to determine whether the electronic components are installed in the correct direction.

### SUMMARY

In accordance with the disclosure, there is provided a chassis including a case having a first opening and a second opening and configured to allow an electronic component to enter the case through the first opening, a lock member including a press member located outside the case and a limit member located inside the case along a first direction of the first opening, and an elastic member. A first part of the elastic member is fixed to an outer contour of the case. The press member is configured to press the elastic member to cause a second part of the elastic member to enter the case through the second opening, to form a locked state. The elastic member is configured to exert an elastic force to cause the second part to exit the case through the second opening when the press member is not pressing the elastic member, to form an unlocked state. The limit member is configured to, when the electronic component is being inserted through the first opening with an insertion member of the electronic component located in the first direction, be driven by the insertion member to move so that the press member does not press the elastic member to cause the elastic member to be in the unlocked state. The elastic member is configured to be in the locked state to allow the second part to abut the electronic component when the electronic component is being inserted through the first opening with the insertion member located in a second direction. An angle is formed between an axial direction of the first opening and an axial direction of the second opening.

Also in accordance with the disclosure, there is provided an electronic device including an electronic component including an insertion member, and a chassis. The chassis includes a case having a first opening and a second opening and configured to allow an electronic component to enter the case through the first opening, a lock member including a press member located outside the case and a limit member located inside the case along a first direction of the first opening, and an elastic member. A first part of the elastic member is fixed to an outer contour of the case. The press member is configured to press the elastic member to cause a second part of the elastic member to enter the case through the second opening, to form a locked state. The elastic member is configured to exert an elastic force to cause the second part to exit the case through the second opening when the press member is not pressing the elastic member, to form an unlocked state. The limit member is configured to, when the electronic component is being inserted through the first opening with an insertion member of the electronic component located in the first direction, be driven by the insertion member to move so that the press member does not press the elastic member to cause the elastic member to be in the unlocked state. The elastic member is configured to be in the locked state to allow the second part to abut the electronic component when the electronic component is being inserted through the first opening with the insertion member located in a second direction. An angle is formed between an axial direction of the first opening and an axial direction of the second opening.

### BRIEF DESCRIPTION OF THE DRAWINGS

FIG. 1 is a schematic structural diagram of an electronic device consistent with the disclosure when a first elastic member is in an unlocked state.

FIG. 2 is an enlarged view of part A in FIG. 1.

FIG. 3 is a schematic structural diagram of an electronic device consistent with the disclosure when a first elastic member is in a locked state.

FIG. 4 is an enlarged view of part B in FIG. 3.

FIG. 5 is a schematic exploded view of an electronic device consistent with the present disclosure.

FIG. 6 is a schematic structural diagram of an electronic component in the electronic device consistent with the present disclosure.

FIG. 7 is a schematic structural diagram of a case of a chassis consistent with the present disclosure.

FIG. 8 is a schematic structural diagram showing cooperation of a lock member, a second elastic member, and a rotation shaft in the chassis consistent with the present disclosure.

FIG. 9 is a schematic structural diagram of a lock member of a chassis consistent with the present disclosure.

FIG. 10 is a schematic structural diagram of a protective cover of a chassis consistent with the present disclosure.

### REFERENCE NUMERALS

1—Chassis; 11—Case; 111—First Opening; 112—Second Opening; 12—Lock member; 121—Press member; 1211—First Limiting Protrusion; 122—Limit member; 13—First Elastic Member; 131—First part; 132—Second part; 14—Rotation shaft; 15—Protective Cover; 151—First Limit groove; 16—Second Elastic Member; 2—Electronic Component; 21—Insertion member.

### DETAILED DESCRIPTION OF THE EMBODIMENTS

Unless there is a conflict, embodiments, as well as technical features in the embodiments, of the present disclosure can be combined with each other. The detailed description should be understood as an explanation of the present disclosure and should not be regarded as a limitation of this disclosure.

To further clarify the objectives, technical solutions, and advantages of the present disclosure, the specific technical solutions of the present disclosure will be further described below in conjunction with the accompanying drawings. The following embodiments are intended to illustrate this disclosure and are not intended to limit its scope.

In the present disclosure, the terms “first” and “second” are used for descriptive purposes only and should not be construed as indicating or implying relative importance or implicitly specifying the number of the technical features indicated. Therefore, features specified as “first” or “second” may explicitly or implicitly include one or more of such features. In the description of the present disclosure, unless otherwise specified, “plurality” means two or more.

Furthermore, in the present disclosure, directional terms such as “upper,” “lower,” “left,” and “right” are defined relative to the schematic placement of components in the accompanying drawings. These directional terms are relative concepts, used for relative description and clarification, and may vary depending on the placement of components in the accompanying drawings.

In the present disclosure, unless otherwise specified or limited, the term “connected” should be understood broadly. For example, “connection” can mean fixed or detachable connection, or being integrated; it can mean direct connection or indirect connection through an intermediary.

In the present disclosure, the terms “comprise,” “include,” or any other variations thereof are intended to encompass non-exclusive inclusion, such that a process, method, article, or apparatus comprising a list of elements includes not only those elements but also other elements not explicitly listed, or elements inherent to such process, method, article, or apparatus. Without further limitation, an element specified by the phrase “comprising a . . . ” does not preclude the presence of additional identical elements in the process, method, article, or apparatus comprising that element.

In the present disclosure, words such as “exemplary” or “for example” are used to indicate examples, illustrations, or explanations. Any embodiment or design described as “exemplary” or “for example” in the present disclosure should not be construed as preferred or advantageous over other embodiments or designs. Rather, the use of words such as “exemplary” or “for example” is intended to present the relevant concepts in a specific manner.

Embodiments of the present disclosure provide an electronic device. The electronic device may be a laptop computer, a desktop computer, a workstation, or a power supply. Embodiment of the present disclosure are not limited to this. In one embodiment of the present disclosure, the electronic device is a power supply.

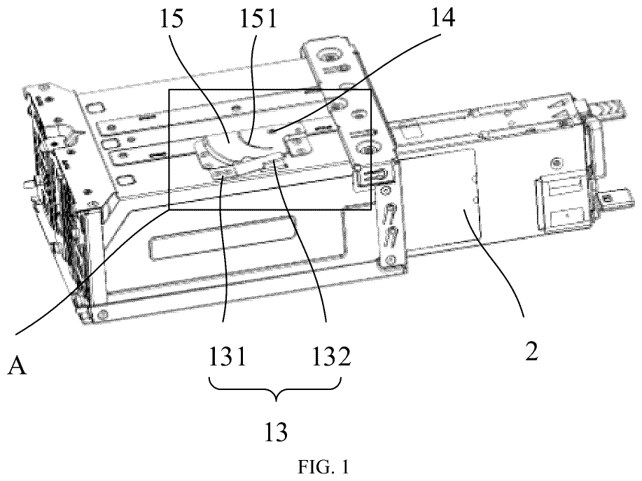

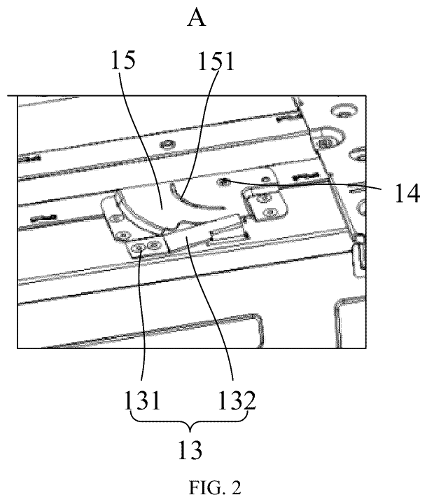

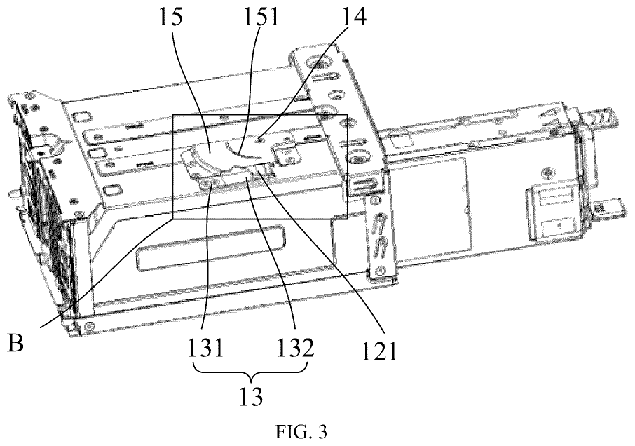

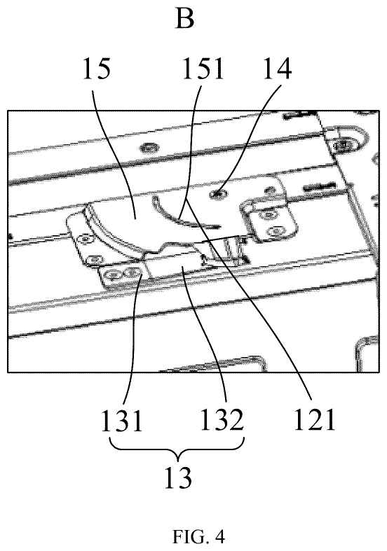

Referring to FIGS. 1-4, an embodiment of the present disclosure provides an electronic device. The electronic device includes an electronic component 2 and a chassis 1. Here, the electronic component 2 can be a central processing unit (CPU), which serves as the operation control center of the electronic device and is a final execution unit for information processing and program running. The CPU is installed in the chassis 1. The electronic component 2 may also be a graphics processing unit (GPU) of the electronic device, also known as a display core, a display chip, or a visual processor. It serves as a coprocessor unit for processing graphics and graphics operation of the electronic device. The GPU is installed in the chassis 1. The electronic component 2 can also be a power supply (PC power supply unit, PSU) of the electronic device, and the electronic component 2 is responsible for converting standard AC power into low-voltage stable DC power for use by other components in the electronic device. The PSU is installed in the chassis 1. In one implementation provided in the present disclosure, the electronic component 2 is a PSU.

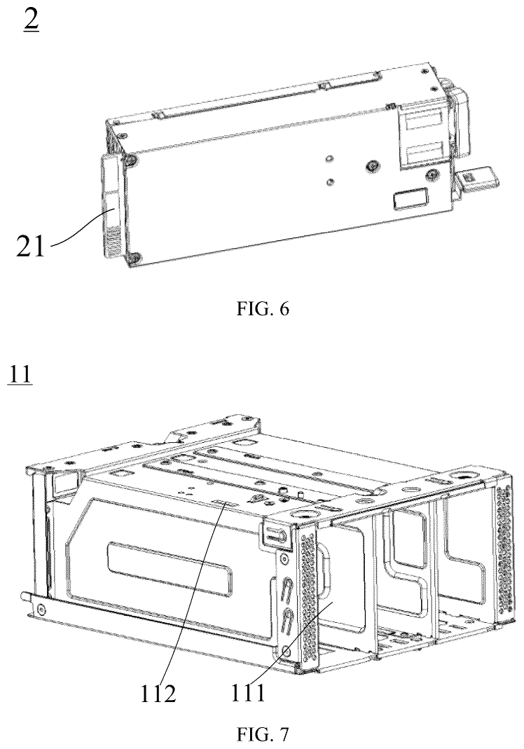

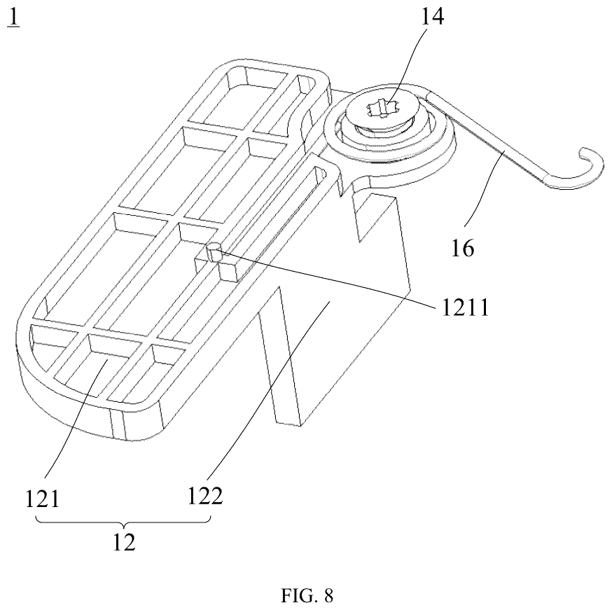

Referring to FIGS. 1, 3, and 5-7, embodiments of the present disclosure further provides a chassis 1, to address the difficulty of determining whether the electronic component 2 is inserted incorrectly during the process of being inserted into the chassis 1. The chassis 1 can be applied to the electronic device provided in the present disclosure. Specifically, the chassis 1 includes a case 11, a lock member 12, and a first elastic member 13. A first opening 111 and a second opening 112 are provided on the case 11, and the electronic component 2 is inserted into the case 11 through the first opening 111. The lock member 12 includes a press member 121 located outside the case 11 and a limit member 122 located inside the case 11 along a first direction of the first opening 111. A first part 131 of the first elastic member 13 is fixed at an outer contour of the case 11. The first elastic member 13 can be pressed by the press member 121, forcing a second part 132 of the first elastic member 13 enter into case 11 through the second opening 112, forming a locked state. When the press member 121 is not pressing the elastic member, the elastic force of the first elastic member 13 causes the second part 132 to exit the case 11 through the second opening 112, forming an unlocked state. When the insertion member 21 of the electronic component 2 is located along the first direction, the insertion member 21 drives the limit member 122 to move so that the press member 121 does not press the first elastic member 13, and the first elastic member 13 is in the unlocked state. When the insertion member 21 is located along the second direction within the case 11, the first elastic member 13 is in the locked state, and the electronic component 2 abuts the second part 132. An angle is formed between the axial directions of the first opening 111 and the second opening 112.

Consistent with the disclosure, the electronic component 2 is inserted into the case 11 through the first opening 111. Correspondingly, an insertion slot is provided in the case 11. The electronic component 2 enters the case 11 through the first opening 111, and the insertion member 21 of the electronic component 2 is inserted in the case 11. During the insertion process, the insertion member 21 of the electronic component 2 should first enter the interior of the case 11.

Consistent with the disclosure, the first elastic member 13 may be an extension spring, a compression spring, a paddle spring, or a coil spring.

Consistent with the disclosure, the first part 131 of the first elastic member 13 is fixed to the outer contour of the case 11. The first part 131 of the first elastic member 13 may be fixed to the outer contour of the case 11 in a non-detachable manner. For example, the first part 131 of the first elastic member 13 may be adhesively fixed to the outer contour of the case 11; or, in another example, the first part 131 of the first elastic member 13 may be welded to the outer contour of the case 11. Of course, the first part 131 of the first elastic member 13 may also be detachably fixed to the outer contour of the case 11. For example, the first part 131 of the first elastic member 13 may be screwed to the outer contour of the case 11; or, in another example, the first part 131 of the first elastic member 13 may be snap-fitted to the outer contour of the case 11.

Consistent with the disclosure, the first part 131 of the first elastic member 13 is fixed to the outer contour of the case 11. The first elastic member 13 can be pressed by the press member 121, so that the second part 132 of the first elastic member 13 enters the case 11 through the second opening 112, forming a locked state. When the press member 121 is not pressing the elastic member, the elastic force of the first elastic member 13 causes the second part 132 to exit the case 11 through the second opening 112, forming an unlocked state. The pressing force applied by the press member 121 is in the opposite direction to the elastic force of the first elastic member 13. For example, if the pressing force required by the press member 121 is in the direction of gravity, the elastic force of the first elastic member 13 is in the direction of antigravity. Or, if the pressing force required by the press member 121 is in the direction of antigravity, the elastic force of the first elastic member 13 is in the direction of gravity.

Consistent with the disclosure, the lock member 12 includes a limit member 122 located along a first direction of the first opening 111 within the case 11. When the insertion member 21 of the electronic component 2 is located in the first direction, the insertion member 21 drives the limit member 122 to move so that the press member 121 does not press the first elastic member 13, and the first elastic member 13 is in an unlocked state. When the insertion member 21 is located along a second direction within the case 11, the first elastic member 13 is in a locked state, and the electronic component 2 abuts the second part 132. In other words, only when the insertion member 21 of the electronic component 2 is located along the first direction can the insertion member 21 drive the limit member 122 to move. Correspondingly, when the insertion member 21 of the electronic component 2 is located along the second direction, the insertion member 21 cannot drive the limit member 122 to move.

Consistent with the disclosure, the insertion member 21 drives the limit member 122 to move so that the press member 121 does not press the first elastic member 13. The insertion member 21 can drive the limit member 122 to move linearly or arcuately.

Consistent with the disclosure, when the insertion member 21 of the electronic component 2 is located along the first direction, the insertion member 21 drives the limit member 122 to move so that the press member 121 does not press the first elastic member 13, and the first elastic member 13 is in the unlocked state. The insertion member 21 drives the limit member 122 to move, and on the premise that the press member 121 does not press the first elastic member 13, the position of the limit member 122 within the case 11 should not affect the normal insertion of the electronic component 2.

The chassis 1 in the present disclosure is provided with a press member 121 located outside the case 11 and a limit member 122 located inside the case 11 along a first direction of the first opening 111, and also a first elastic member 13. When the insertion member 21 of the electronic component 2 is located along the first direction, the insertion member 21 drives the limit member 122 to move so that the press member 121 does not press the first elastic member 13. The elastic force of the first elastic member 13 causes the second part 132 of the first elastic member 13 to exit the case 11 through the second opening 112. The first elastic member 13 is in an unlocked state, and the electronic component 2 can continue to be inserted. When the insertion member 21 of the electronic component 2 is located along the second direction, the electronic component 2 abuts the second part 132 of the first elastic member 13 in the case 11 through the second opening 112. The first elastic member 13 is in a locked state, and the electronic component 2 cannot continue to be inserted. In this way, the state of the first elastic member 13 can be used to determine whether the insertion direction of the electronic component 2 is correct; and whether the electronic component 2 can continue to be inserted can also be used to determine whether the insertion direction of the electronic component 2 is correct, so as to reduce the phenomenon of the electronic component 2 being inserted in the wrong direction.

During the process of the electronic component 2 being inserted into the chassis 1, the electronic component 2 is prone to be inserted in the wrong direction. To solve this, the embodiments of the present disclosure provide a lock member 12 and a first elastic member 13. The interaction and cooperation between the lock member 12, the first elastic member 13 and the insertion member 21 of the electronic component 2 makes it possible to determine whether the electronic component 2 is inserted incorrectly only by observing the state of the first elastic member 13 or whether the electronic component 2 can continue to be inserted. In this way, the phenomenon of the electronic component 2 being inserted incorrectly can be reduced.

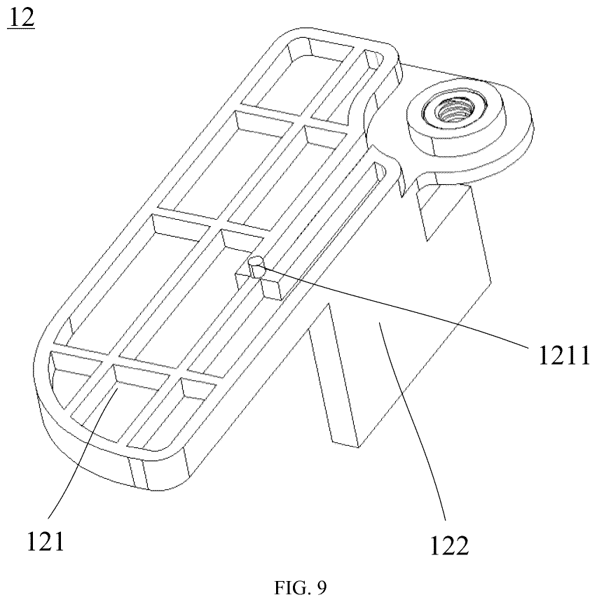

Referring to FIGS. 1, 2, 3, 4, and 8, an embodiment of the present disclosure provides a chassis 1 having a limit member 122 located at an insertion path for inserting an electronic component 2 into the case 11 through a first opening 111. When the insertion member 21 is located along the first direction, the insertion member 21 drives the limit member 122 to a non-insertion path for inserting the electronic component 2 into the case 11 through the first opening 111.

In the present disclosure, the limit member 122 is located along a insertion path for inserting the electronic component 2 into the case 11 through the first opening 111. The insertion path refers to a path that the electronic component 2 must pass through to be inserted into the case 11 through the first opening 111. Without this path, the electronic component 2 cannot be inserted into the case 11 through the first opening 111. Accordingly, when the insertion member 21 is along the first direction, the insertion member 21 drives the limit member 122 to a non-insertion path for inserting the electronic component 2 into the case 11 through the first opening 111. The non-insertion path refers to a path that the electronic component 2 does not need to pass through when inserted into the case 11 through the first opening 111. In other words, the path does not affect the insertion of the electronic component 2 into the case 11 through the first opening 111.

The chassis 1 in the present disclosure has the limit member 122 positioned at the insertion path for the electronic component 2 to be inserted into the case 11 through the first opening 111. This ensures that when the insertion member 21 of the electronic component 2 is along the first direction, the insertion member 21 of the electronic component 2 can accurately drive the electronic device 2. Furthermore, when the insertion member 21 of the electronic component 2 is located along the second direction, the insertion member 21 of the electronic component 2 can accurately abut the insertion member 21. On this basis, when the insertion member 21 drives the limit member 122 to move to a non-insertion path for the electronic component 2 to be inserted into the case 11 through the first opening 111, the electronic component 2 can be smoothly inserted into the case 11 through the first opening 111 when the insertion member 21 of the electronic component 2 is located along the first direction.

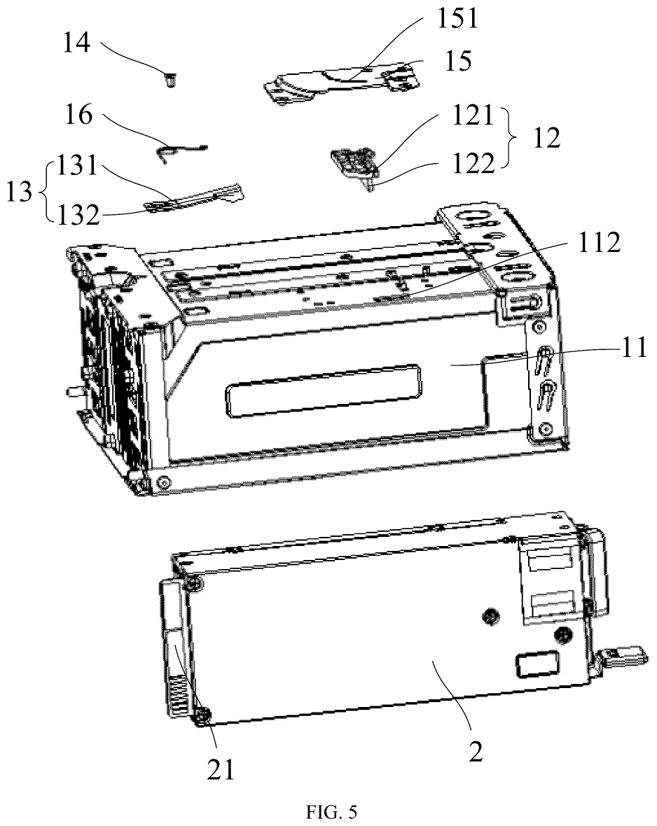

Referring to FIGS. 5, 6, 7, 8, and 9, an embodiment of the present disclosure provides a chassis 1, where the chassis 1 further includes a rotation shaft 14 arranged between the case 11 and the lock member 12. When the insertion member 21 is located along the first direction, the insertion member 21 drives the limit member 122 to rotate along the axial direction of the rotation shaft 14. The axial direction of the rotation shaft 14 is parallel to the axial direction of the second opening 112.

Consistent with the disclosure, the chassis 1 further includes a rotation shaft 14, which is arranged between the case 11 and the lock member 12. A first rotating hole can be formed in the case 11, and a second rotating hole can be formed in the lock member 12. The rotation shaft 14 can be sequentially inserted into the first rotating hole and the second rotating hole. The axial directions of the first rotating hole and the second rotating hole are parallel to the axial direction of the second opening 112. Of course, the rotation shaft 14 can be directly arranged on the case 11, and the second rotating hole can be formed in the lock member 12. The rotation shaft 14 can be inserted into the second rotating hole. The axial direction of the second rotating hole is parallel to the axial direction of the second opening 112. Furthermore, the first rotating hole can be formed in the case 11, and the rotation shaft 14 can be directly arranged on the lock member 12. The rotation shaft 14 can extend into the first rotating hole, and the axial direction of the first rotating hole is parallel to the axial direction of the second opening 112.

Consistent with the disclosure, the rotation shaft 14 is arranged between the case 11 and the lock member 12, where the rotation shaft 14 can be arranged between the case 11 and the press member 121. Of course, the rotation shaft 14 can also be arranged between the case 11 and the limit member 122. Furthermore, the rotation shaft 14 can also be arranged between the connection of the press member 121 and the limit member 122 and the case 11.

The chassis 1 in the present disclosure utilizes a rotation shaft 14 arranged between the case 11 and the lock member 12. This allows the insertion member 21 to drive the limit member 122 to rotate axially along the rotation shaft 14 when the insertion member 21 is located along the first direction, thereby unlocking the first elastic member 13. This provides a simple structure and easy implementation.

Referring to FIGS. 5-8 and 10, the embodiments of the present disclosure provide a chassis 1, which also includes a protective cover 15. The protective cover 15 is fixed to the case 11, and the protective cover 15 and an outer contour of the case 11 enclose a protective space, within which the press member 121 is located.

Consistent with the disclosure, the protective cover 15 is fixed to the case 11. The protective cover 15 can be fixed to the case 11 in a non-detachable manner, such as by welding the protective cover 15 to the case 11 or by adhesively bonding the protective cover 15 to the case 11. Of course, the protective cover 15 can also be fixed to the case 11 in a detachable manner, such as by screwing the protective cover 15 to the case 11 or by snapping the protective cover 15 to the case 11. In one possible embodiment of the present disclosure, the protective cover 15 is screwed to the case 11.

In the present disclosure, the protective cover 15 is fixed to the case 11, and the protective cover 15 and the outer contour of the case 11 form a protective space. This allows the press member 121 to be located within the protective space, isolated from the outside. This protects the press member 121 from damage.

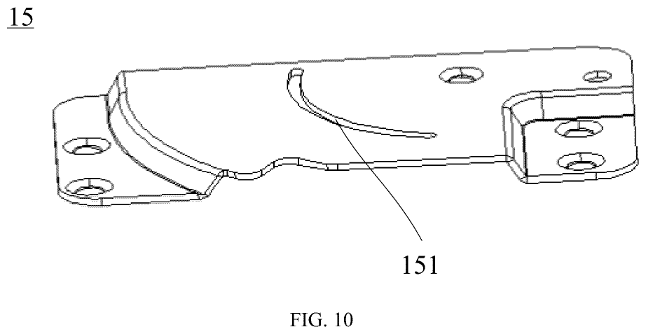

Referring to FIGS. 9 and 10, an embodiment of the present disclosure provides a chassis 1. A first limit groove 151 is provided on the protective cover 15. A first protrusion is provided on a side of the press member 121 facing away from the case 11. The first protrusion cooperates with the first limit groove 151. The extending direction of the first limit groove 151 is the same as the moving direction of a limit member 122 driven by an insertion member 21.

In this embodiment, the first protrusion cooperates with the first limit groove 151, and the extending direction of the first limit groove 151 is the same as the moving direction of the limit member 122 driven by the insertion member 21 means that when the insertion member 21 drives the limit member 122, the first protrusion can move within the first limit groove 151 along the extending direction of the first limit groove 151.

Consistent with the present disclosure, the extending direction of the first limit groove 151 is the same as the moving direction of the insertion member 21 driving the limit member 122. For example, when the moving direction of the insertion member 21 driving the limit member 122 is a straight line, the extending direction of the first limit groove 151 should also be a straight line. As another example, when the moving direction of the insertion member 21 driving the limit member 122 is an arc line, the extending direction of the first limit groove 151 should also be an arc line.

According to the chassis 1 in the present disclosure, the extending direction of the first limit groove 151 is the same as the moving direction of the insertion member 21 driving the limit member 122, and the first protrusion cooperates with the first limit groove 151, so that the first protrusion can also move in the first limit groove 151 along the extending direction of the first limit groove 151 while the insertion member 21 driving the limit member 122. Therefore, the first limit groove 151 can play a role in guiding and limiting, and the accuracy and stability of the insertion member 21 driving the limit member 122 can be improved.

Referring to FIGS. 9 and 10, an embodiment of the present disclosure provides a chassis 1 that further includes a second elastic member 16 arranged between the protective cover 15 and the press member 121 or between the case 11 and the press member 121. The elastic force of the second elastic member 16 provides a restoring force from the press member 121 not pressing the first elastic member 13 to the press member 121 pressing the first elastic member 13.

Consistent with the disclosure, the second elastic member 16 is arranged between the protective cover 15 and the press member 121 or between the case 11 and the press member 121. The second elastic member 16 can be arranged between the protective cover 15 and the press member 12, or the second elastic member 16 can be arranged between the case 11 and the press member 121.

Consistent with the disclosure, the elastic force of the second elastic member 16 provides a restoring force from the press member 121 not pressing the first elastic member 13 to the press member 121 pressing the first elastic member 13. The second elastic member 16 can be a coil spring, a torsion spring, or even a paddle spring. In one embodiment of the present disclosure, the second elastic member 16 is a torsion spring.

According to the chassis 1 in the present disclosure, the second elastic member 16 is arranged between the protective cover 15 and the press member 121 or between the case 11 and the press member 121, and the elastic force of the second elastic piece 16 provides a restoring force from press member 121 not pressing the first elastic member 13 the press member 121 pressing the first elastic member 13. This can make the first elastic member 13 in a locked state without applying external force, facilitating the next insertion of the electronic component 2 and saving time and cost.

Referring to FIGS. 9 and 10, an embodiment of the present disclosure provides a chassis 1 in which the second elastic member 16 is a torsion spring. The second elastic member 16 includes a first end, a second end, and an intermediate end located between the first end and second end. The first end is fixed to the press member 121, the second end is fixed to the case 11 or the protective cover 15, and the intermediate end is fixed to the rotation shaft 14.

According to the chassis 1 in the present disclosure, the second elastic member 16 is a torsion spring. The first end of the second elastic member 16 is fixed to the press member 121, the second end of the second elastic member 16 is fixed to the case 11 or the protective cover 15, and the intermediate end of the second elastic member 16 is fixed to the rotation shaft 14. This ensures that the position of the second elastic member 16 remains relatively stable during the process of the elastic force of the second elastic piece 16 providing a restoring force from press member 121 not pressing the first elastic member 13 the press member 121 pressing the first elastic member 13, thereby enhancing the stability of the second elastic member 16.

Referring to FIGS. 9 and 10, according to the chassis 1 in the embodiments of the present disclosure, a second limit groove is formed on the press member 121, and at least a portion of the second elastic member 16 is located within the second limit groove. A third limit groove is provided on the case 11 or the protective cover 15, and at least a portion of the second elastic member 16 is located in the third limit groove.

According to the chassis 1 in the present disclosure, the second limit groove is formed on the press member 121 and the third limit groove is formed on the case 11 or the protective cover 15, at least a portion of the second retaining member is located in the second limit groove, and at least a portion of the second elastic member 16 is located in the third limit groove. This allows for a compact structure of the chassis 1, facilitating a miniaturized design.

According to the chassis 1 in this embodiment of the present disclosure, the first elastic member 13 is a paddle spring. The first end of the paddle spring is a first part 131. The second end of the paddle spring is provided with a second protrusion facing inside of the case 11. The second protrusion is a second part 132.

Any modifications, equivalent substitutions, and improvements made within the spirit and principles of the present disclosure are intended to be included within the scope of protection of the present disclosure.

What is claimed is:

1. A chassis comprising:
a case having a first opening and a second opening, the case being configured to allow an electronic component to enter the case through the first opening;
a lock member including a press member located outside the case and a limit member located inside the case along a first direction of the first opening; and
an elastic member, a first part of the elastic member being fixed to an outer contour of the case;
wherein:
the press member is configured to press the elastic member to cause a second part of the elastic member to enter the case through the second opening, to form a locked state;
the elastic member is configured to exert an elastic force to cause the second part to exit the case through the second opening when the press member is not pressing the elastic member, to form an unlocked state;
the limit member is configured to, when the electronic component is being inserted through the first opening with an insertion member of the electronic component located in the first direction, be driven by the insertion member to move so that the press member does not press the elastic member to cause the elastic member to be in the unlocked state;
the elastic member is configured to be in the locked state to allow the second part to abut the electronic component when the electronic component is being inserted through the first opening with the insertion member located in a second direction; and
an angle is formed between an axial direction of the first opening and an axial direction of the second opening.

2. The chassis according to claim 1, wherein the limit member is located at an insertion path along which the electronic component is inserted into the case through the first opening and is configured to be driven by the insertion member to move away from the insertion path when the electronic component is being inserted into the case through the first opening with the insertion member located in the first direction.

3. The chassis according to claim 1, further comprising:
a rotation shaft arranged between the case and the lock member;
wherein:
the limit member is configured to be driven by the insertion member to rotate about an axial direction of the rotation shaft when the insertion member is located in the first direction; and
the axial direction of the rotation shaft is parallel to the axial direction of the second opening.

4. The chassis according to claim 1, further comprising:
a protective cover fixed to the case and forming a protective space together with the outer contour of the case;
wherein the press member is located within the protective space.

5. The chassis according to claim 4, wherein:
the protective cover is provided with a limit groove, and one side of the press member facing away from the case is provided with a protrusion configured to cooperate with the limit groove; and
an extending direction of the limit groove is same as a moving direction of the limit member driven by the insertion member.

6. The chassis according to claim 4,
wherein the elastic member is a first elastic member;
the chassis further comprising:
a second elastic member arranged between the protective cover and the press member or between the case and the press member, an elastic force of the second elastic member providing a restoring force from the press member not pressing the first elastic member to the press member pressing the first elastic member.

7. The chassis according to claim 6, wherein the second elastic member includes a torsion spring, and the second elastic member includes a first end, a second end, and an intermediate end between the first end and second end, the first end being fixed to the press member, the second end being fixed to the case or the protective cover, and the intermediate end being fixed to the rotation shaft.

8. The chassis according to claim 7, wherein the press member is provided with a limit groove, and at least a portion of the second elastic member is located within the limit groove.

9. The chassis according to claim 7, wherein the case or the protective cover is provided with a limit groove, and at least a portion of the second elastic member is located within the third limit groove.

10. The chassis according to claim 1, wherein the elastic member includes a paddle spring, a first end of the paddle spring is the first part, a second end of the spring paddle is provided with a protrusion facing inside of the case, and the protrusion is the second part.

11. An electronic device comprising:
an electronic component including an insertion member;
a chassis including:
a case having a first opening and a second opening, the case being configured to allow the electronic component to enter the case through the first opening;
a lock member including a press member located outside the case and a limit member located inside the case along a first direction of the first opening; and
an elastic member, a first part of the elastic member being fixed to an outer contour of the case;
wherein:
the press member is configured to press the elastic member to cause a second part of the elastic member to enter the case through the second opening, to form a locked state;
the elastic member is configured to exert an elastic force to cause the second part to exit the case through the second opening when the press member is not pressing the elastic member, to form an unlocked state;
the limit member is configured to, when the electronic component is being inserted through the first opening with an insertion member of the electronic component located in the first direction, be driven by the insertion member to move so that the press member does not press the elastic member to cause the elastic member to be in the unlocked state;
the elastic member is configured to be in the locked state to allow the second part to abut the electronic component when the electronic component is being inserted through the first opening with the insertion member located in a second direction; and
an angle is formed between an axial direction of the first opening and an axial direction of the second opening.

12. The electronic device according to claim 11, wherein the limit member is located at an insertion path along which the electronic component is inserted into the case through the first opening and is configured to be driven by the insertion member to move away from the insertion path when the electronic component is being inserted into the case through the first opening with the insertion member located in the first direction.

13. The electronic device according to claim 11, wherein:
the chassis further includes a rotation shaft arranged between the case and the lock member;
the limit member is configured to be driven by the insertion member to rotate about an axial direction of the rotation shaft when the insertion member is located in the first direction; and
the axial direction of the rotation shaft is parallel to the axial direction of the second opening.

14. The electronic device according to claim 1, wherein:
the chassis further includes a protective cover fixed to the case and forming a protective space together with the outer contour of the case; and
the press member is located within the protective space.

15. The electronic device according to claim 14, wherein:
the protective cover is provided with a limit groove, and one side of the press member facing away from the case is provided with a protrusion configured to cooperate with the limit groove; and
an extending direction of the limit groove is same as a moving direction of the limit member driven by the insertion member.

16. The electronic device according to claim 14, wherein:
the elastic member is a first elastic member; and
the chassis further includes:
a second elastic member arranged between the protective cover and the press member or between the case and the press member, an elastic force of the second elastic member providing a restoring force from the press member not pressing the first elastic member to the press member pressing the first elastic member.

17. The electronic device according to claim 16, wherein the second elastic member includes a torsion spring, and the second elastic member includes a first end, a second end, and an intermediate end between the first end and second end, the first end being fixed to the press member, the second end being fixed to the case or the protective cover, and the intermediate end being fixed to the rotation shaft.

18. The electronic device according to claim 17, wherein the press member is provided with a limit groove, and at least a portion of the second elastic member is located within the limit groove.

19. The electronic device according to claim 17, wherein the case or the protective cover is provided with a limit groove, and at least a portion of the second elastic member is located within the third limit groove.

20. The electronic device according to claim 11, wherein the elastic member includes a paddle spring, a first end of the paddle spring is the first part, a second end of the spring paddle is provided with a protrusion facing inside of the case, and the protrusion is the second part.
